(19) United States
(12) Patent Application Publication
(10) Pub. No.: US 2014/0158410 A1
(43) Pub. Date: Jun. 12, 2014

(54) POLYIMIDE, COPPER-CLAD LAMINATE, FLEXIBLE PRINTED CIRCUIT BOARD, AND METHOD FOR MANUFACTURING THE FLEXIBLE PRINTED CIRCUIT BOARD

(71) Applicant: Zhen Ding Technology Co., Ltd., Tayuan (TW)

(72) Inventor: MING-JAAN HO, New Taipei (TW)

(73) Assignee: ZHEN DING TECHNOLOGY CO., LTD., Tayuan (TW)

(21) Appl. No.: 14/093,669

(22) Filed: Dec. 2, 2013

(30) Foreign Application Priority Data
Dec. 11, 2012 (CN) 2012105299190

(51) Int. Cl. H05K 1/09; H05K 3/02

(52) U.S. Cl. CPC H05K 1/095; H05K 3/02
USPC 174/254; 525/421; 427/99.4; 428/458; 428/336

(57) ABSTRACT

A polyimide is formed by dehydrating a polyamic acid. The polyamic acid is formed by polymerizing a diamine and a fluorine dianhydride. The diamine is 2,2′-bis[4-(4-aminophenoxy) phenyl] propane, and the fluorine dianhydride is 2,2-bis(3,4-dicarboxyphenyl) hexafluoropropane dianhydride. When a color of the polyimide is defined by Lab color space, b component is set from about −10 to about +10. The disclosure further relates to a copper-clad laminate, a flexible printed circuit, and a method for manufacturing the flexible printed circuit.

### BACKGROUND

1. Technical Field

The present disclosure relates to flexible printed circuit (FPC) manufacturing field, and particularly to a polyimide, a copper-clad laminate, an FPC, and a method for manufacturing the FPC.

2. Description of Related Art

An FPC includes an insulating substrate, and the insulating substrate is made of golden brown polyimide. When a color of the golden brown polyimide is defined using Lab color space, b component is set from 40 to 70, and a light transmittance of the golden brown polyimide is low (i.e. less than about 30%).

Therefore, it is desirable to provide an improved polyimide, a copper-clad laminate, an FPC, and a method for manufacturing the FPC that can overcome the above-mentioned limitations.

### BRIEF DESCRIPTION OF THE DRAWINGS

Many aspects of the embodiments should be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a cross-sectional view of a copper foil coated with a coating layer, according to one exemplary embodiment.

FIG. 2 is a cross-sectional view of a copper-clad laminate after the coating layer of FIG. 1 is heated.

FIG. 3 is a cross-sectional view of an FPC, according to another exemplary embodiment.

FIG. 4 is a chemical equation of diamine reacted with fluorine dianhydride to obtain a polyamic acid, and the polyamic acid is dehydrated to obtain a polyimide.

### DETAILED DESCRIPTION

A polyimide is formed by dehydrating a polyamic acid. The polyamic acid is formed by polymerizing a diamine and a fluorine dianhydride.

The diamine can be 2,2′-bis[4-(4-aminophenoxy) phenyl] propane (p-BAPP), and the fluorine dianhydride can be 2,2-bis(3,4-dicarboxyphenyl) hexafluoropropane dianhydride (6FDA).

The polyimide is colorless and transparent. A pyrolysis temperature of the polyimide is from about 400° C. to about 450° C. In a Lab color space, when L=0, it indicates that the color is black. When L=100, it indicates that the color is white. When a is a negative value, it indicates that the color is green. When a is a positive value, it indicates that the color is red. When b is a negative value, it indicates that the color is blue; and when b is a positive value, it indicates that the color is yellow. When a color of the polyimide is defined using the Lab color space, b component of the polyimide is set from −10 to +10, it indicates that the polyimide is colorless.

A method for manufacturing a flexible printed circuit (FPC) includes the following steps.

In step S1, the polyamic acid is manufactured.

In particular, the step S1 includes the following steps.

Firstly, the diamine is dissolved in a solvent to obtain a mixed solvent. The diamine can be p-BAPP, and the solvent can be N,N-Dimethylacetamide. In an nitrogen environment, the p-BAPP is added into N,N-Dimethylacetamide to obtain a mixed liquid, and the mixed liquid is stirred for about 4 hours to about 5 hours until the p-BAPP is completely dissolved in the N,N-Dimethylacetamide.

The fluorine dianhydride is added into the mixed solvent to obtain the polyamic acid. The fluorine dianhydride can be 2,2′-(3,4-two carboxylic acid) hexafluoropropane dianhydride, and the mixed solvent and the fluorine dianhydride are stirred for 24 hours until the fluorine dianhydride is completely dissolved in the mixed solvent, and the fluorine dianhydride is polymerized with the diamine to obtain the polyamic acid. In particular, an amidocyanogen of the diamine is polymerized with an acid anhydride of the fluorine dianhydride, and thus obtaining an amido and a carboxyl.

During the manufacturing process of the polyamic acid, the weight of the diamine is about 6% to about 10% of the weight of the polyamic acid, and the weight of the fluorine dianhydride is about 6% to about 13% of the weight of the polyamic acid, and the remaining of the polyamic acid is the solvent.

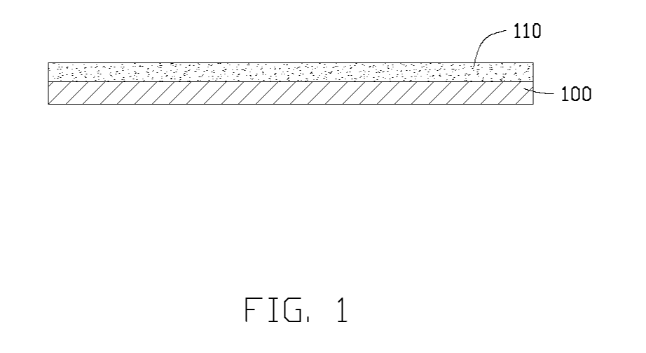

In step S2, FIG. 1 shows that the polyamic acid is coated to a surface of a copper foil 100 to form a coating layer 110. A thickness of the coating layer 110 can be about 8 micrometers to about 25 micrometers.

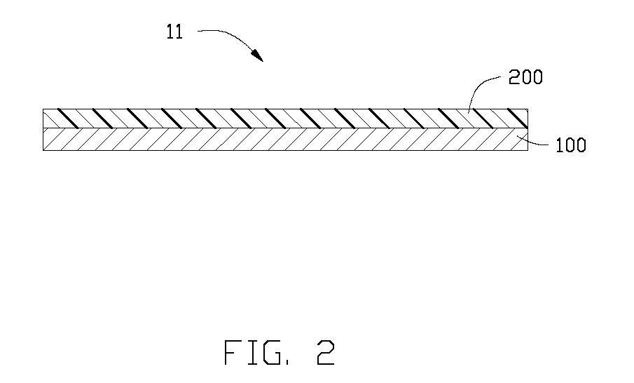

In step S3, FIG. 2 shows that the coating layer 110 is heated, and thus the polyamic acid of the coating layer 110 is dehydrated to form the fluorine polyimide, and a base layer 200 is obtained. The copper foil 100 and the base layer 200 cooperatively form the copper-clad laminate 11.

In step S3, during the curing process of the coating layer 110, an amido reacts with a carboxyl of the polyamic acid to form a hydrone. Therefore, the polyimide is obtained.

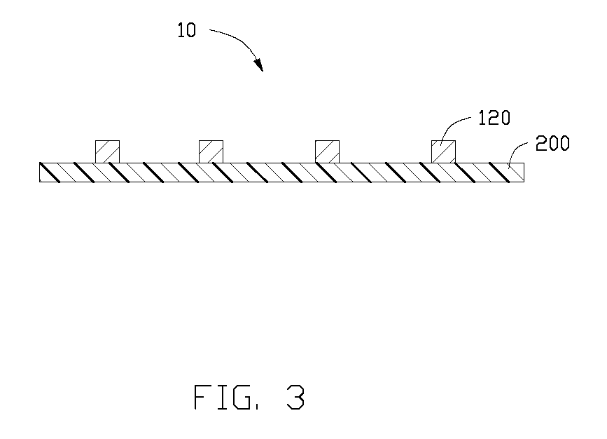

In step S4, referring to FIG. 3, the copper foil 100 is processed to form a wiring layer 120, and thus an FPC 10 is obtained.

In this step, a portion of the copper foil 100 is removed using image transferring method or chemical etching method to obtain the FPC 10. A light transmittance of the base layer 200 is greater than 81.5%.

The manufacturing method of the FPC 10 further includes a step: a transparent protection film (not shown) is pressed on the wiring layer 120 to protect the wiring layer 120. The transparent protection film can be made of polyimide or polythylene terephthalate (PET).

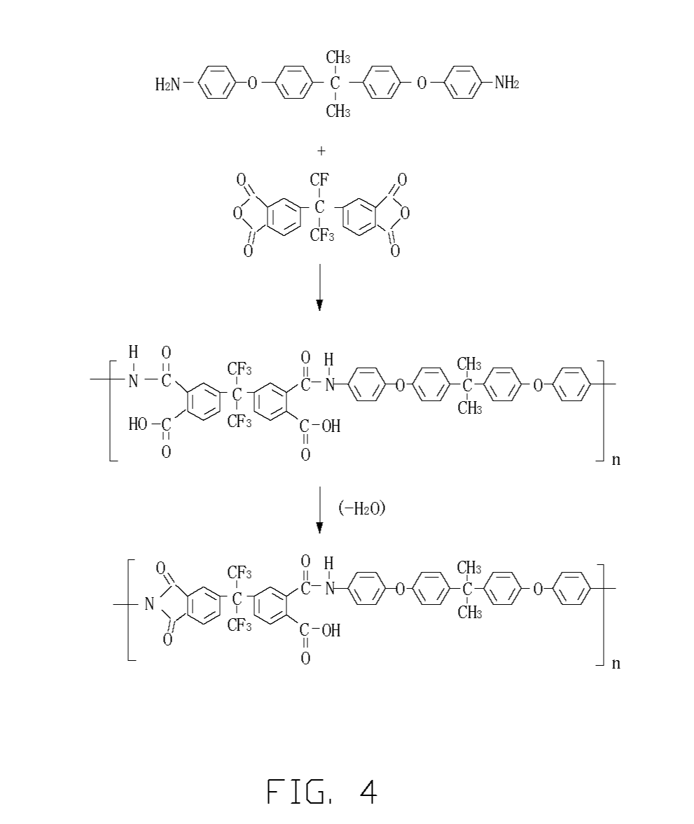

FIG. 2 shows a copper-clad laminate 11. The copper-clad laminate 11 includes a copper foil 100 and a base layer 200 formed on the copper foil 100. The base layer 200 is made of polyimide. Also referring to FIG. 4, the polyimide is formed by dehydrating a polyamic acid. The polyamic acid is formed by polymerizing a diamine and a fluorine dianhydride. The diamine can be p-BAPP, and the fluorine dianhydride can be 6FDA. The base layer 200 is colorless and transparent. The pyrolysis temperature of the polyimide is from about 400° C. to about 450° C. The thickness of the base layer 200 is from about 8 micrometers to about 25 micrometers. The light transmittance of the base layer 200 is greater than 81.5%.

FIG. 3 shows an FPC 10. The FPC 10 includes a base layer 200 and a wiring layer 120 formed on the base layer 200. The base layer 200 is made of polyimide. The polyimide is formed by dehydrating a polyamic acid. The polyamic acid is formed by polymerizing a diamine and a fluorine dianhydride. The diamine can be p-BAPP, and the fluorine dianhydride can be 6FDA. The base layer 200 is colorless and transparent. The pyrolysis temperature of the polyimide is about 400° C. to about 450° C. The thickness of the base layer 200 is about 8 micrometers to about 25 micrometers. The light transmittance of the base layer 200 is greater than 81.5%.

Referring to table 1, an optical density of the polyimide is less than an optical density of the golden brown polyimide of related art, and when light rays of which the wavelength is 700 nanometers (nm) transmit in the polyimide and the golden brown polyimide of related art, a light transmittance of the polyimide is greater than a light transmittance of the golden brown polyimide of related art, therefore, the polyimide is colorless, and when the polyimide is used as a base layer of the FPC, the portion of the FPC except the wiring layer is colorless. In addition, because a pyrolysis temperature of the polyimide is about 430° C. which is higher than a temperature of surface mounting process (i.e. 200° C.), thus it is easy to assemble the FPC and other elements.

| | Polyimide of this | Golden brown polyimide |
|---|---|---|
| | invention | of related art |
| Optical density | 0.05 | 0.17 |
| Light transmittance (%) | 81.5 | 23.2 |
| Pyrolysis temperature (° C.) | 430 | 540 |

Furthermore, because the base layer is formed by a coating method, the thickness of the base layer can be effectively reduced.

In other embodiments, the polyimide and the copper-clad laminate also can be used in a rigid-flexible PCB.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A polyimide being formed by dehydrating a polyamic acid, wherein the polyamic acid is formed by polymerizing a diamine and a fluorine dianhydride, the diamine is 2,2′-bis[4-(4-aminophenoxy) phenyl] propane, and the fluorine dianhydride is 2,2-bis(3,4-dicarboxyphenyl) hexafluoropropane dianhydride, when a color of the polyimide is defined by Lab color space, b component is set from −10 to +10.

2. The polyimide of claim 1, wherein a pyrolysis temperature of the polyimide is from about 400° C. to about 450° C.

3. A flexible printed circuit, comprising:
a base layer made of a polyimide, wherein the polyimide being formed by dehydrating a polyamic acid, wherein the polyamic acid is formed by polymerizing a diamine and a fluorine dianhydride, the diamine is 2,2′-bis[4-(4-aminophenoxy) phenyl] propane, and the fluorine dianhydride is 2,2-bis(3,4-dicarboxyphenyl) hexafluoropropane dianhydride, when a color of the polyimide is defined by Lab color space, b component is set from −10 to +10; and
a wiring layer formed on the base layer.

4. The flexible printed circuit of claim 3, wherein a thickness of the base layer is from about 8 micrometers to about 25 micrometers.

5. The flexible printed circuit of claim 3, wherein a light transmittance of the base layer is greater than 80%.

6. The flexible printed circuit of claim 3, wherein a pyrolysis temperature of the polyimide is from about 400° C. to about 450° C.

7. A method for manufacturing the flexible printed circuit, comprising:
forming a polyamic acid by polymerizing a diamine and a fluorine dianhydride, wherein the diamine is 2,2′-bis[4-(4-aminophenoxy) phenyl] propane, and the fluorine dianhydride is 2,2-bis(3,4-dicarboxyphenyl) hexafluoropropane dianhydride;
coating the polyamic acid on a copper foil to obtain a coating layer;
curing the coating layer to dehydrate the polyamic acid, thus obtaining a fluorine polyimide, and the coating layer becoming a base layer, wherein when a color of the polyimide is defined by Lab color space, b component is set from −10 to +10; and
processing the copper foil to form a wiring layer, thus the flexible printed circuit is obtained.

8. The method of claim 7, wherein the step of forming a polyamic acid further comprises:
dissolving the diamine in a solvent to obtain a mixed solvent; and
adding the fluorine dianhydride to the mixed solvent, and the fluorine dianhydride being polymerized with the diamine to obtain the polyamic acid.

9. The method of claim 8, wherein the weight of the diamine is from about 6% to about 10% of the weight of the polyamic acid, and the weight of the fluorine dianhydride is from about 6% to about 13% of the weight of the polyamic acid, and the remaining of the polyamic acid is the solvent.

10. A copper-clad laminate, comprising:
a copper foil; and
a base layer formed on the copper foil and made of the a polyimide, wherein the polyimide being formed by dehydrating a polyamic acid, wherein the polyamic acid is formed by polymerizing a diamine and a fluorine dianhydride, the diamine is 2,2′-bis[4-(4-aminophenoxy) phenyl] propane, and the fluorine dianhydride is 2,2-bis(3,4-dicarboxyphenyl) hexafluoropropane dianhydride, when a color of the polyimide is defined by Lab color space, b component is set from about −10 to about +10.

11. The copper-clad laminate of claim 10, wherein a pyrolysis temperature of the polyimide is from about 400° C. to about 450° C.

12. The copper-clad laminate of claim 10, wherein a thickness of the base layer is from about 8 micrometers to about 25 micrometers.

13. The copper-clad laminate of claim 10, wherein a light transmittance of the base layer is greater than 80%.
